(19) United States
(12) Patent Application Publication
(10) Pub. No.: US 2019/0034021 A1
(43) Pub. Date: Jan. 31, 2019

(54) TOUCH SCREEN AND DISPLAY DEVICE

(71) Applicants: BOE Technology Group Co., Ltd., Beijing (CN); Chengdu BOE Optoelectronics Technology Co., Ltd., Sichuan (CN)

(72) Inventors: Biyu Zhao, Beijing (CN); Kwang Gyun Jang, Beijing (CN)

(21) Appl. No.: 15/991,622

(22) Filed: May 29, 2018

(30) Foreign Application Priority Data
Jul. 28, 2017 (CN) 201710633589.2

(51) Int. Cl. G06F 3/041; G06F 3/044

(52) U.S. Cl. CPC G06F 3/0416; H01L 27/323; G06F 3/044

(57) ABSTRACT

The disclosure discloses a touch screen and a display device, where the touch screen includes an upper substrate and a lower substrate arranged opposite to each other, and a force sensing electrode element located on a side of the lower substrate facing the upper substrate.

### CROSS-REFERENCE TO RELATED APPLICATION

This application claims the benefit of Chinese Patent Application No. 201710633589.2, filed with the Chinese Patent Office on Jul. 28, 2017, which is hereby incorporated by reference in its entirety.

### TECHNICAL FIELD

This disclosure relates to the field of display technologies, and particularly to a touch screen and a display device.

### DESCRIPTION OF THE RELATED ART

The force sensing or force touch technology refers to a technology capable of detecting a force applied from the outside, and this technology has been applied for long in the industry control, medical, and other fields. At present, a force or a pressure can be sensed in the field of displays, and particularly the field of mobile phones or flat panel displays by adding an extra structure to a backlight component of a liquid crystal display panel, or a middle frame component of a mobile phone, and this design requires a structural design of the liquid crystal display panel or the mobile phone to be modified, and also the detection accuracy of this design may be limited due to a significant assembling tolerance.

Accordingly it is highly desirable for those skilled in the art to address the issue of how to sense a force or a pressure with high detection accuracy while the structural design of the terminal is less significantly modified.

### SUMMARY

Embodiments of the disclosure provide a touch screen and a display device.

In an aspect, embodiments of the disclosure provide a touch screen, including an upper substrate and a lower substrate arranged opposite to each other, and a force sensing electrode element located on a side of the lower substrate facing the upper substrate.

In some embodiments, the lower substrate includes a base substrate, and a poly-silicon layer, a gate insulation layer, a gate metal layer, an interlayer dielectric layer, a source and drain metal layer, a planarization layer, an anode layer and a pixel definition layer arranged on the base substrate in that order; wherein the force sensing electrode element is arranged in a same layer with the anode layer on the planarization layer; an orthographic projection of the force sensing electrode element onto the base substrate does not overlap with an orthographic projection of the anode layer onto the base substrate, but overlaps with an orthographic projection of the pixel definition layer onto the base substrate.

In some embodiments, the force sensing electrode element and the anode layer are formed in a same patterning process.

In some embodiments, the lower substrate includes a base substrate, and a poly-silicon layer, a gate insulation layer, a gate metal layer, an interlayer dielectric layer, a source and drain metal layer, a planarization layer, an anode layer and a pixel definition layer arranged on the base substrate in that order; wherein the lower substrate further includes a buffer layer located between the base substrate and the poly-silicon layer; wherein the force sensing electrode element is arranged on the buffer layer, and is covered by the gate insulation layer; an orthographic projection of the force sensing electrode element onto the base substrate does not overlap with an orthographic projection of the gate metal layer onto the base substrate, and an orthographic projection of the source and drain metal layer onto the base substrate; and the orthographic projection of the force sensing electrode element onto the base substrate and an orthographic projection of the anode layer onto the base substrate do not overlap with each other in a first direction; the first direction is an extension direction of a gate in the gate metal layer.

In some embodiments, the gate metal layer includes a first gate metal layer and a second gate metal layer arranged sequentially in a stack in a direction away from the poly-silicon layer; and the force sensing electrode element and the first gate metal layer are formed in a same patterning process.

In some embodiments, the lower substrate includes a base substrate, and a poly-silicon layer, a gate insulation layer, a gate metal layer, an interlayer dielectric layer, a source and drain metal layer, a planarization layer, an anode layer and a pixel definition layer arranged on the base substrate in that order; wherein the force sensing electrode element is arranged on the interlayer dielectric layer, and is covered by the planarization layer; an orthographic projection of the force sensing electrode element onto the base substrate does not overlap with an orthographic projection of the gate metal layer onto the base substrate, and an orthographic projection of the source and drain metal layer onto the base substrate; and the orthographic projection of the force sensing electrode element onto the base substrate and an orthographic projection of the anode layer onto the base substrate do not overlap with each other in a first direction; the first direction is an extension direction of a gate in the gate metal layer.

In some embodiments, the gate metal layer includes a first gate metal layer and a second gate metal layer arranged sequentially in a stack in a direction away from the poly-silicon layer; and the force sensing electrode element and the second gate metal layer are formed in a same patterning process.

In some embodiments, the lower substrate further includes a common electrode arranged on the pixel definition layer; and the force sensing electrode element and the common electrode form a capacitor structure.

In some embodiments, the upper substrate includes a touch panel substrate, an encapsulation substrate located on a side of the touch panel substrate facing the lower substrate, and a touch electrode element located on a side of the touch panel substrate facing away from the lower substrate; wherein the force sensing electrode element and the touch electrode element form a capacitor structure.

In some embodiments, the touch electrode element includes a drive touch electrode element and a sensing touch electrode element.

In some embodiments, the touch screen further includes a force sensing detection circuit connected with the force sensing electrode element; the force sensing detection circuit includes a channel selection circuit, an analog to digital converter, and a micro controller unit, wherein: the channel selection circuit is configured to strobe a signal output by a force sensing electrode element subjected to a pressure applied by a user, and to input the signal to the analog to digital converter; the analog to digital converter is configured to perform analog to digital conversion on the signal input by the channel selection circuit; and the micro controller unit is configured to detect a magnitude and position of the pressure applied by the user according to a digital signal input by the analog to digital converter.

In another aspect, the embodiments of the disclosure further provide a display device including a touch screen; wherein the touch screen includes an upper substrate and a lower substrate arranged opposite to each other, and a force sensing electrode element located on a side of the lower substrate facing the upper substrate.

In some embodiments, the lower substrate includes a base substrate, and a poly-silicon layer, a gate insulation layer, a gate metal layer, an interlayer dielectric layer, a source and drain metal layer, a planarization layer, an anode layer and a pixel definition layer arranged on the base substrate in that order; wherein the force sensing electrode element is arranged in a same layer with the anode layer on the planarization layer, and an orthographic projection of the force sensing electrode element onto the base substrate does not overlap with an orthographic projection of the anode layer onto the base substrate, but overlaps with an orthographic projection of the pixel definition layer onto the base substrate; or the force sensing electrode element is arranged on the interlayer dielectric layer and is covered by the planarization layer, the orthographic projection of the force sensing electrode element onto the base substrate does not overlap with an orthographic projection of the gate metal layer onto the base substrate and an orthographic projection of the source and drain metal layer onto the base substrate, and the orthographic projection of the force sensing electrode element onto the base substrate and the orthographic projection of the anode layer onto the base substrate do not overlap with each other in a first direction, wherein the first direction is an extension direction of a gate in the gate metal layer; or the lower substrate further includes a buffer layer located between the base substrate and the poly-silicon layer, the force sensing electrode element is arranged on the buffer layer and is covered by the gate insulation layer, the orthographic projection of the force sensing electrode element onto the base substrate does not overlap with the orthographic projection of the gate metal layer onto the base substrate and the orthographic projection of the source and drain metal layer onto the base substrate, and the orthographic projection of the force sensing electrode element onto the base substrate and the orthographic projection of the anode layer onto the base substrate do not overlap with each other in the first direction.

In some embodiments, the gate metal layer includes a first gate metal layer and a second gate metal layer arranged sequentially in a stack in a direction away from the poly-silicon layer; and when the force sensing electrode element is arranged in the same layer with the anode layer on the planarization layer, the force sensing electrode element and the anode layer are formed in a same patterning process; or when the force sensing electrode element is arranged on the buffer layer and covered by the gate insulation layer, the force sensing electrode element and the first gate metal layer are formed in a same patterning process; or when the force sensing electrode element is arranged on the interlayer dielectric layer and covered by the planarization layer, the force sensing electrode element and the second gate metal layer are formed in a same patterning process.

In some embodiments, the lower substrate further includes a common electrode arranged on the pixel definition layer; and the force sensing electrode element and the common electrode form a capacitor structure.

In some embodiments, the upper substrate includes a touch panel substrate, an encapsulation substrate located on a side of the touch panel substrate facing the lower substrate, and a touch electrode element located on a side of the touch panel substrate facing away from the lower substrate; wherein the force sensing electrode element and the touch electrode element form a capacitor structure.

In some embodiments, the touch electrode element includes a drive touch electrode element and a sensing touch electrode element.

In some embodiments, the touch screen further includes a force sensing detection circuit connected with the force sensing electrode element; the force sensing detection circuit includes a channel selection circuit, an analog to digital converter, and a micro controller unit, wherein: the channel selection circuit is configured to strobe a signal output by a force sensing electrode element subjected to a pressure applied by a user, and to input the signal to the analog to digital converter; the analog to digital converter is configured to perform analog to digital conversion on the signal input by the channel selection circuit; and the micro controller unit is configured to detect a magnitude and position of the pressure applied by the user according to a digital signal input by the analog to digital converter.

### BRIEF DESCRIPTION OF THE DRAWINGS

In order to make the technical solutions according to embodiments of the disclosure more apparent, the drawings to which reference is made in the description of the embodiments will be introduced below in brief, and apparently the drawings to be described below are only some embodiments of the disclosure, and those ordinarily skilled in the art can further derive from these drawings other drawings without any inventive effort.

FIG. 1 is a schematic structural diagram of a touch screen according to the embodiments of the disclosure;

FIG. 2A is a first schematic diagram of detecting a signal on a touch screen according to the embodiments of the disclosure;

FIG. 2B is a second schematic diagram of detecting a signal on a touch screen according to the embodiments of the disclosure; and

FIG. 3 is a flow chart of detecting a signal on a touch screen according to the embodiments of the disclosure.

### DETAILED DESCRIPTION OF THE EMBODIMENTS

In order to make the objects, technical solutions, and advantages of this discourse more apparent, the disclosure will be described below in further details with reference to the drawings, and apparently the embodiments to be described below are only a part but not all of the embodiments of the disclosure. Based upon the embodiments here of the disclosure, all the other embodiments which can occur to those ordinarily skilled in the art without any inventive effort shall fall into the scope of the disclosure as claimed.

The shapes and sizes of respective components in the drawing are not intended to reflect any real proportion, but only intended to illustrate the disclosure.

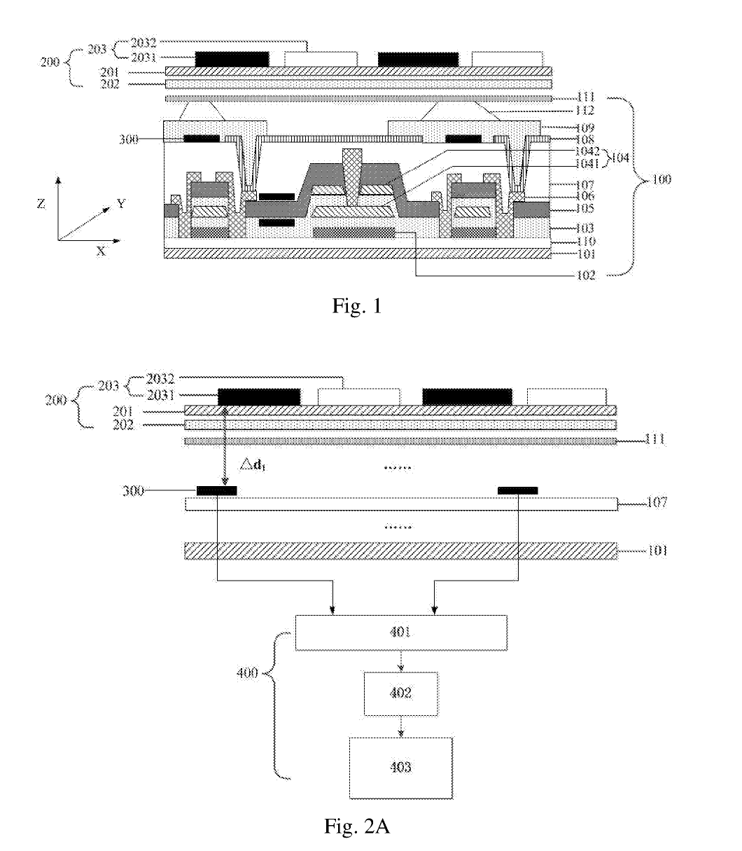

As illustrated in FIG. 1, the embodiments of the disclosure provide a touch screen including an upper substrate 200 and a lower substrate 100 arranged opposite to each other, and a force sensing electrode element 300 located on a side of the lower substrate 100 facing the upper substrate 200.

In the touch screen above according to the embodiments of the disclosure, the force sensing electrode element is designed on the side of the lower substrate facing the upper substrate, i.e. between the upper substrate and the lower substrate, while the structural design of the terminal is less significantly modified, so no extra structure will be added to the terminal from the outside, thus improving a limited assembly tolerance, and enabling a force touch function with higher detection accuracy.

In some embodiments, there are a plurality of force sensing electrode elements 300 arranged on the side of the lower substrate 100 facing the upper substrate 200.

In some embodiments, as illustrated in FIG. 1, the lower substrate 100 includes a base substrate 101, and a poly-silicon layer 102, a gate insulation layer 103, a gate metal layer 104, an interlayer dielectric layer 105, a source and drain metal layer 106, a planarization layer 107, an anode layer 108 and a pixel definition layer 109 arranged on the base substrate 101 in that order; wherein the force sensing electrode element(s) 300 is (or are) arranged in a same layer with the anode layer 108 on the planarization layer 107, and an orthographic projection of the force sensing electrode element(s) 300 onto the base substrate 101 does not overlap with an orthographic projection of the anode layer 108 onto the base substrate 101, but overlaps with an orthographic projection of the pixel definition layer 109 onto the base substrate 101.

In some embodiments, the force sensing electrode element(s) 300 arranged in the same layer with the anode layer 108 on the planarization layer 107, and the anode layer 108 are formed in a same patterning process.

In some embodiments, as illustrated in FIG. 1, the lower substrate 100 not only includes the base substrate 101, and the poly-silicon layer 102, the gate insulation layer 103, the gate metal layer 104, the interlayer dielectric layer 105, the source and drain metal layer 106, the planarization layer 107, the anode layer 108 and the pixel definition layer 109 arranged on the base substrate 101 in that order, but further includes a buffer layer 110 located between the base substrate 101 and the poly-silicon layer 102; wherein the force sensing electrode element(s) 300 is (or are) arranged on the buffer layer 110, and is (or are) covered by the gate insulation layer 103; the orthographic projection of the force sensing electrode element(s) 300 onto the base substrate 101 does not overlap with an orthographic projection of the gate metal layer 104 onto the base substrate 101, and an orthographic projection of the source and drain metal layer 106 onto the base substrate 101; and the orthographic projection of the force sensing electrode element(s) 300 onto the base substrate 101 and the orthographic projection of the anode layer 108 onto the base substrate 101 do not overlap with each other in a first direction (i.e. Y direction as illustrated in FIG. 1); the first direction is an extension direction of a gate in the gate metal layer 104.

In some embodiments, the gate metal layer 104 includes a first gate metal layer 1041 and a second gate metal layer 1042 arranged sequentially in a stack in a direction away from the poly-silicon layer 102; the force sensing electrode element(s) 300 arranged on the buffer layer 110 and covered by the gate insulation layer 103, and the first gate metal layer 1041 are formed in a same patterning process.

It shall be noted that, there can also be arranged with a gate insulation layer between the first gate metal layer 1041 and the second gate metal layer 1042.

In some embodiments, as illustrated in FIG. 1, the lower substrate 100 includes the base substrate 101, and the poly-silicon layer 102, the gate insulation layer 103, the gate metal layer 104, the interlayer dielectric layer 105, the source and drain metal layer 106, the planarization layer 107, the anode layer 108 and the pixel definition layer 109 arranged on the base substrate 101 in that order; wherein the force sensing electrode element(s) 300 is (or are) arranged on the interlayer dielectric layer 105, and is (or are) covered by the planarization layer 107; the orthographic projection of the force sensing electrode element(s) 300 onto the base substrate 101 does not overlap with the orthographic projection of the gate metal layer 104 onto the base substrate 101, and the orthographic projection of the source and drain metal layer 106 onto the base substrate 101; and the orthographic projection of the force sensing electrode element(s) 300 onto the base substrate 101 and the orthographic projection of the anode layer 108 onto the base substrate 101 do not overlap with each other in the first direction (i.e. Y direction as illustrated in FIG. 1); the first direction is the extension direction of the gate in the gate metal layer 104.

In some embodiments, the gate metal layer 104 includes the first gate metal layer 1041 and the second gate metal layer 1042 arranged sequentially in a stack in the direction away from the poly-silicon layer 102; the force sensing electrode element(s) 300 arranged on the interlayer dielectric layer 105 and covered by the planarization layer 107, and the second gate metal layer 1042 are formed in a same patterning process.

It shall be noted that, the touch screen above according to the embodiments of the disclosure includes one or several kinds of force sensing electrode elements, such as the force sensing electrode element(s) arranged in the same layer with the anode layer on the planarization layer, the force sensing electrode element(s) arranged on the buffer layer and covered by the gate insulation layer, and the force sensing electrode element(s) arranged on the interlayer dielectric layer and covered by the planarization layer. For example, in FIG. 1, it is illustrated by taking the touch screen including all the three kinds of force sensing electrode elements as an example; and in FIG. 2A and FIG. 2B, it is illustrated by taking the touch screen including the force sensing electrode element(s) arranged in the same layer with the anode layer on the planarization layer 107 as an example.

In some embodiments, as illustrated in FIG. 1, the lower substrate 100 further includes a common electrode (cathode) 111 arranged on the pixel definition layer 109; and the force sensing electrode element(s) 300 and the common electrode 111 form a capacitor structure.

In addition, it shall be noted that, structures, materials, and functions of respective layers of the lower substrate 100 are similar to or the same as corresponding elements in the touch screen in the related art, so a repeated description thereof will be omitted here.

In some embodiments, the upper substrate 200 includes a touch panel (TP) substrate 201, an encapsulation substrate 202 located on a side of the touch panel substrate 201 facing the lower substrate 100 and configured to encapsulate the lower substrate, and a touch electrode element 203 located on a side of the touch panel substrate 201 facing away from the lower substrate 100; wherein the force sensing electrode element(s) 300 and the touch electrode element 203 form a capacitor structure.

In some embodiments, the touch electrode element 203 includes a drive touch electrode Tx element 2031 and a sensing touch electrode Rx element 2032, where either of the drive touch electrode Tx element 2031 and the sensing touch electrode Rx element 2032, and the force sensing electrode element(s) 300 can form a capacitor structure.

As can be apparent, in the touch screen above according to the embodiments of the disclosure, the force sensing electrode element(s) 300 can form capacitor structures with a plurality of electrode elements, such as the common electrode 111, the drive touch electrode Tx element 2031 and the sensing touch electrode Rx element 2032.

Examples thereof will be described below.

In a first instance, the drive touch electrode Tx element 2031 and the force sensing electrode element(s) 300 form a capacitor structure. When the touch screen is pressed, there is a change in capacitance between the drive touch electrode Tx element 2031 and the force sensing electrode element(s) 300, so that the magnitude and position of the pressure can be detected by detecting the change in capacitance between them.

In a second instance, the sensing touch electrode Rx element 2032 and the force sensing electrode element(s) 300 form a capacitor structure. When the touch screen is pressed, there is a change in capacitance between the sensing touch electrode Rx element 2032 and the force sensing electrode element(s) 300, so that the magnitude and position of the pressure can be detected by detecting the change in capacitance between them.

In a third instance, the common electrode 111 and the force sensing electrode element(s) 300 form a capacitor structure. When the touch screen is pressed, there is a change in capacitance between the common electrode 111 and the force sensing electrode element(s) 300, so that the magnitude and position of the pressure can be detected by detecting the change in capacitance between them.

In some embodiments, the touch screen above according to the embodiments of the disclosure further includes a force sensing detection circuit 400 (not illustrated in FIG. 1, but illustrated in FIG. 2A and FIG. 2B) connected with the force sensing electrode element(s) 300.

Wherein the force sensing detection circuit 400 is configured to detect the magnitude and position of a pressure applied to the touch screen when the touch screen is subjected to the pressure. For example, in a force touch phase, a force sensing signal of the force sensing electrode element(s) 300 is received, and the magnitude and position of the pressure applied to the touch screen are determined by detecting a change in capacitance between the touch electrode element 203 (the drive touch electrode Tx element 2031 and/or the sensing touch electrode Rx element 2032) and the force sensing electrode element(s) 300, or between the common electrode 111 and the force sensing electrode element(s) 300.

In the touch screen above according to the embodiments of the disclosure, when some force sensing electrode element is subjected to a pressure, there are a change in distance, and thus a change in capacitance, between the force sensing electrode element and the touch electrode element, or between the force sensing electrode element and the common electrode, so the force sensing detection circuit is arranged to detect the magnitude and position of the pressure by detecting the change in capacitance to thereby realize the force touch function.

In some embodiments, the force sensing detection circuit 400 includes: a channel selection circuit 401, an Analog to Digital Converter (ADC) 402, and a Micro Controller Unit (MCU) 403, where: the channel selection circuit 401 is configured to strobe a signal output by a force sensing electrode element 300 subjected to a pressure applied by a user, and to input the signal to the ADC 402; the ADC 402 is configured to perform analog to digital conversion on the signal input by the channel selection circuit 401; and the MCU 403 is configured to detect a magnitude and position of the pressure applied by the user according to a digital signal input by the ADC 402.

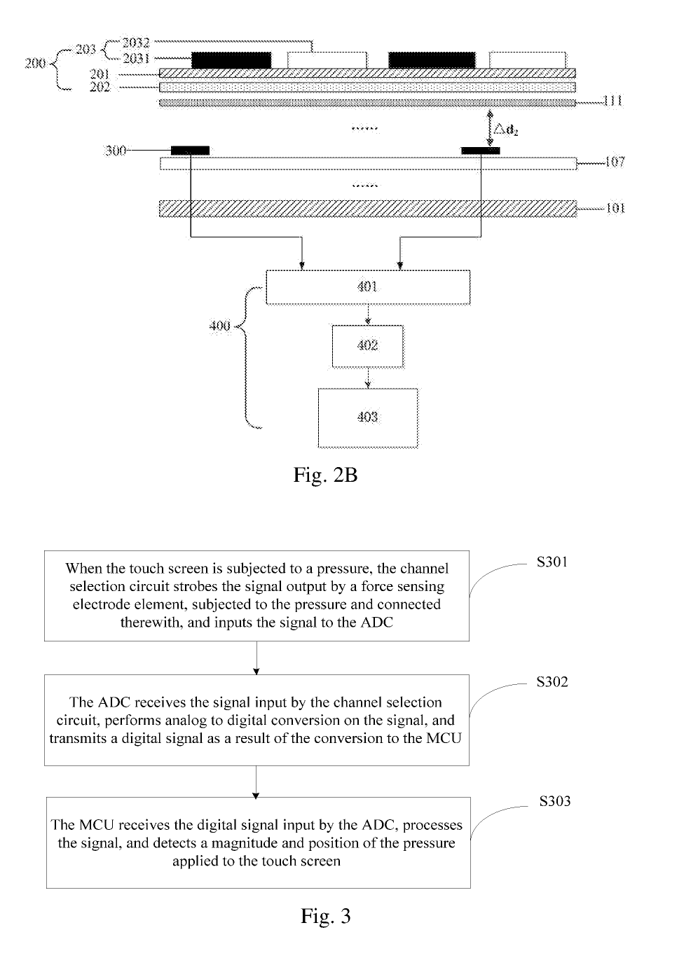

In some embodiments, each force sensing electrode element 300 is electrically connected with the channel selection circuit 401 through a wire corresponding thereto, and as illustrated in FIG. 3, a pressure signal is processed by the three modules, where a processing flow thereof can include the following operations.

In the operation S301, when the touch screen is subjected to a pressure, the channel selection circuit 401 strobes the signal output by a force sensing electrode element, subjected to the pressure and connected therewith, and inputs the signal to the ADC 402.

In the operation S302, the ADC 402 receives the signal input by the channel selection circuit 401, performs analog to digital conversion on the signal, and transmits a digital signal as a result of the conversion to the MCU 403.

In the operation S303, the MCU 403 receives the digital signal input by the ADC 402, processes the signal, and detects a magnitude and position of the pressure applied to the touch screen.

It shall be noted that the particular structure and operating flow of the force sensing detection circuit have been described above only by way of an example, and in a particular implementation, the particular structure and operating flow of the force sensing detection circuit will not be limited to the structure and flow above according to the embodiments of the disclosure, but can alternatively be another structure and flow known to those skilled in the art, and the embodiments of the disclosure will not be limited thereto.

In the touch screen above according to the embodiments of the disclosure, the force sensing electrode element(s) is (or are) arranged between the upper substrate and the lower substrate, and the force sensing electrode element(s) and the touch electrode element form a capacitor structure, or the force sensing electrode element(s) and the common electrode form a capacitor structure; and when some force sensing electrode element is subjected to a pressure, there are a change in distance, and thus a change in capacitance, between the force sensing electrode element and the touch electrode element, or between the force sensing electrode element and the common electrode, so the force sensing detection circuit is arranged to detect the magnitude and position of the pressure by detecting the change in capacitance between the force sensing electrode element (which can be referred to as a lower electrode) and the touch electrode element (which can be referred to as an upper electrode), or between the force sensing electrode element and the common electrode (which can be referred to as an upper electrode) to thereby realize the force touch function. Since the force sensing electrode elements are designed inside the touch screen, the structural design of the display device can be less significantly modified to thereby improve the limited assembling tolerance so as to facilitate higher detection accuracy, thus improving the stability of the structure.

In the touch screen above according to the embodiments of the disclosure, as illustrated in FIG. 2A and FIG. 2B, the spacing between respective force sensing electrode elements 300 and the touch electrode element 203 forming capacitor structures is d₁, and the spacing between the respective force sensing electrode elements 300 and the common electrode 111 forming capacitor structures is d₂, for example, so a capacitance of a capacitor structure formed between a force sensing electrode element 300 and the touch electrode element, or between the force sensing electrode element 300 and the common electrode 111 is defined as in a capacitance equation of C=εS/4πkd, where C represents the capacitance of the capacitor structure formed between the force sensing electrode element 300 and the touch electrode element 203, or between the force sensing electrode element 300 and the common electrode 111; ε represents a dielectric constant of an insulating dielectric at a distance d; S represents an overlapping area between the force sensing electrode element 300 and the touch electrode element 203 or the common electrode 111, where the area is an overlapping area between an orthographic projection of the touch electrode element 203 or the common electrode 111 onto a plane where the force sensing electrode element 300 lies, and the force sensing electrode element 300; k represents an electrostatic constant; and d includes d₁ and d₂, where d₁ represents the spacing between the force sensing electrode element 300 and the touch electrode element 203, and d₂ represents the spacing between the force sensing electrode element 300 and the common electrode 111.

It shall be noted that there is a number of schemes to detect a signal in the touch screen above according to the embodiments of the disclosure.

Examples thereof will be described below.

In a first scheme, as illustrated in FIG. 2A, when there is a pressure at a position of a force sensing electrode element 300, the spacing d1 is decreased, and thus there is an increase in capacitance between the force sensing electrode element 300 and the touch electrode element 203 as per the capacitance equation above, so the magnitude of the pressure can be determined by detecting this change in capacitance.

In a second scheme, as illustrated in FIG. 2B, when there is a pressure at a position of a force sensing electrode element 300, the spacing d2 is decreased, and thus there is an increase in capacitance between the force sensing electrode element 300 and the common electrode 111 as per the capacitance equation above, so the magnitude of the pressure can be determined by detecting this change in capacitance.

In some embodiments, as illustrated in FIG. 1, the lower substrate 100 above according to the embodiments of the disclosure further includes a post spacer 112 located between the pixel definition layer 109 and the common electrode 111.

In the touch screen above according to the embodiments of the disclosure, there is a vacuum layer between the pixel definition layer 109 and the common electrode 111, so there will be not any piezoelectric conversion material to be filled between them, where the deformation of the touch screen being pressed is bore by the post spacer 112, thus lowering a production cost.

In some embodiments, in the touch screen above according to the embodiments of the disclosure, the material and shape of the post spacer 112 will not be limited to any particular material and shape, but may be one of a number of materials and shapes.

In some embodiments, in the touch screen above according to the embodiments of the disclosure, the shape of the force sensing electrode element(s) 300 in use can be a diamond or a square, for example, and a length of the diagonal thereof can be 4 millimeters, for example. Of course, the shape or size thereof can alternatively be another shape or size, although the embodiments of the disclosure will not be limited thereto.

In some embodiments, in the touch screen above according to the embodiments of the disclosure, the TP substrate 201 is typically fit onto the encapsulation substrate 202, and an alignment tolerance due to their fitting is approximately 200 micrometers; and since the size of the diagonal of the force sensing electrode element(s) 300 can be 4 millimeters, for example, the alignment tolerance can be neglected as compared with the 4-millimeter order of magnitude.

Typically the touch density of the touch screen is in the order of millimeters, so in a particular implementation, the distribution density of the force sensing electrode element(s), and their occupied area can be selected according to a desirable force touch density and a desirable screen size to thereby guarantee the desirable touch accuracy. In the touch screen above according to the embodiments of the disclosure, the force sensing electrode element(s) can be distributed in a number of patterns.

Examples thereof will be described below.

In a first pattern, the force sensing electrode elements 300 are arranged directly below and corresponding in a one-to-one manner to respective Tx elements 2031 or respective Rx elements 2032, so that the respective Tx elements 2031 or the respective Rx elements 2032, and their corresponding force sensing electrode elements 300 can form capacitor structures.

In a second pattern, the force sensing electrode elements 300 are arranged directly below a middle of every two adjacent Tx elements 2031 or Rx elements 2032, so that every two adjacent Tx elements 2031 or Rx elements 2032, and their corresponding one of force sensing electrode elements 300 can form a capacitor structure.

Stated otherwise, the number of force sensing electrode elements, and their particular positions in the embodiments of the disclosure will not be limited to any particular setting as long as they and the upper electrode(s) can form capacitor structures.

In a particular implementation, the touch screen above according to the embodiments of the disclosure can be a flexible display screen or can be a rigid display screen, although the embodiments of the disclosure will not be limited thereto.

Based upon the same inventive concept, the embodiments of the disclosure further provide a display device, which can include the touch screen above according to the embodiments of the disclosure. The display device can be a mobile phone, a tablet computer, a TV set, a monitor, a notebook computer, a digital photo frame, a navigator, or any other product or component with a display function. All the other components indispensable to the display device shall readily occur to those ordinarily skilled in the art, so a repeated description thereof will be omitted here, and the embodiments of the disclosure will not be limited thereto. Reference can be made to the description of the touch screen above according to the embodiments of the disclosure for a particular implementation of the display device, so a repeated description thereof will be omitted here.

In the touch screen and the display device above according to the embodiments of the disclosure, the force sensing electrode element(s) is (or are) arranged between the upper substrate and the lower substrate, and the force sensing electrode element(s) and the touch electrode element form a capacitor structure, or the force sensing electrode element(s) and the common electrode form a capacitor structure; and when some force sensing electrode element is subjected to a pressure, there are a change in distance, and thus a change in capacitance, between the force sensing electrode element and the touch electrode element, or between the force sensing electrode element and the common electrode, so the force sensing detection circuit is arranged to detect the magnitude and position of the pressure by detecting the change in capacitance between the force sensing electrode element and the touch electrode element, or between the force sensing electrode element and the common electrode to thereby realize the force touch function. Since the force sensing electrode element(s) is (or are) designed inside the touch screen, the structural design of the display device can be less significantly modified to thereby improve the limited assembling tolerance so as to facilitate higher detection accuracy, thus improving the stability of the structure.

Evidently those skilled in the art can make various modifications and variations to the invention without departing from the spirit and scope of the invention. Thus the invention is also intended to encompass these modifications and variations thereto so long as the modifications and variations come into the scope of the claims appended to the invention and their equivalents.

1. A touch screen, comprising an upper substrate and a lower substrate arranged opposite to each other, and a force sensing electrode element located on a side of the lower substrate facing the upper substrate.

2. The touch screen according to claim 1, wherein the lower substrate comprises a base substrate, and a poly-silicon layer, a gate insulation layer, a gate metal layer, an interlayer dielectric layer, a source and drain metal layer, a planarization layer, an anode layer and a pixel definition layer arranged on the base substrate in that order;
wherein the force sensing electrode element is arranged in a same layer with the anode layer on the planarization layer;
an orthographic projection of the force sensing electrode element onto the base substrate does not overlap with an orthographic projection of the anode layer onto the base substrate, but overlaps with an orthographic projection of the pixel definition layer onto the base substrate.

3. The touch screen according to claim 2, wherein the force sensing electrode element and the anode layer are formed in a same patterning process.

4. The touch screen according to claim 1, wherein the lower substrate comprises a base substrate, and a poly-silicon layer, a gate insulation layer, a gate metal layer, an interlayer dielectric layer, a source and drain metal layer, a planarization layer, an anode layer and a pixel definition layer arranged on the base substrate in that order; wherein the lower substrate further comprises a buffer layer located between the base substrate and the poly-silicon layer;
wherein the force sensing electrode element is arranged on the buffer layer, and is covered by the gate insulation layer;
an orthographic projection of the force sensing electrode element onto the base substrate does not overlap with an orthographic projection of the gate metal layer onto the base substrate, and an orthographic projection of the source and drain metal layer onto the base substrate; and
the orthographic projection of the force sensing electrode element onto the base substrate and an orthographic projection of the anode layer onto the base substrate do not overlap with each other in a first direction; the first direction is an extension direction of a gate in the gate metal layer.

5. The touch screen according to claim 4, wherein the gate metal layer comprises a first gate metal layer and a second gate metal layer arranged sequentially in a stack in a direction away from the poly-silicon layer; and
the force sensing electrode element and the first gate metal layer are formed in a same patterning process.

6. The touch screen according to claim 1, wherein the lower substrate comprises a base substrate, and a poly-silicon layer, a gate insulation layer, a gate metal layer, an interlayer dielectric layer, a source and drain metal layer, a planarization layer, an anode layer and a pixel definition layer arranged on the base substrate in that order;
wherein the force sensing electrode element is arranged on the interlayer dielectric layer, and is covered by the planarization layer;
an orthographic projection of the force sensing electrode element onto the base substrate does not overlap with an orthographic projection of the gate metal layer onto the base substrate, and an orthographic projection of the source and drain metal layer onto the base substrate; and
the orthographic projection of the force sensing electrode element onto the base substrate and an orthographic projection of the anode layer onto the base substrate do not overlap with each other in a first direction; the first direction is an extension direction of a gate in the gate metal layer.

7. The touch screen according to claim 6, wherein the gate metal layer comprises a first gate metal layer and a second gate metal layer arranged sequentially in a stack in a direction away from the poly-silicon layer; and
the force sensing electrode element and the second gate metal layer are formed in a same patterning process.

8. The touch screen according to claim 2, wherein the lower substrate further comprises a common electrode arranged on the pixel definition layer; and the force sensing electrode element and the common electrode form a capacitor structure.

9. The touch screen according to claim 4, wherein the lower substrate further comprises a common electrode arranged on the pixel definition layer; and the force sensing electrode element and the common electrode form a capacitor structure.

10. The touch screen according to claim 6, wherein the lower substrate further comprises a common electrode arranged on the pixel definition layer; and the force sensing electrode element and the common electrode form a capacitor structure.

11. The touch screen according to claim 1, wherein the upper substrate comprises a touch panel substrate, an encapsulation substrate located on a side of the touch panel substrate facing the lower substrate, and a touch electrode element located on a side of the touch panel substrate facing away from the lower substrate;
wherein the force sensing electrode element and the touch electrode element form a capacitor structure.

12. The touch screen according to claim 11, wherein the touch electrode element comprises a drive touch electrode element and a sensing touch electrode element.

13. The touch screen according to claim 1, wherein the touch screen further comprises a force sensing detection circuit connected with the force sensing electrode element; the force sensing detection circuit comprises a channel selection circuit, an analog to digital converter, and a micro controller unit, wherein:
the channel selection circuit is configured to strobe a signal output by a force sensing electrode element subjected to a pressure applied by a user, and to input the signal to the analog to digital converter;
the analog to digital converter is configured to perform analog to digital conversion on the signal input by the channel selection circuit; and
the micro controller unit is configured to detect a magnitude and position of the pressure applied by the user according to a digital signal input by the analog to digital converter.

14. A display device, comprising a touch screen; wherein the touch screen comprises an upper substrate and a lower substrate arranged opposite to each other, and a force sensing electrode element located on a side of the lower substrate facing the upper substrate.

15. The display device according to claim 14, wherein the lower substrate comprises a base substrate, and a poly-silicon layer, a gate insulation layer, a gate metal layer, an interlayer dielectric layer, a source and drain metal layer, a planarization layer, an anode layer and a pixel definition layer arranged on the base substrate in that order;
wherein the force sensing electrode element is arranged in a same layer with the anode layer on the planarization layer; an orthographic projection of the force sensing electrode element onto the base substrate does not overlap with an orthographic projection of the anode layer onto the base substrate, but overlaps with an orthographic projection of the pixel definition layer onto the base substrate;
or,
the force sensing electrode element is arranged on the interlayer dielectric layer, and is covered by the planarization layer; the orthographic projection of the force sensing electrode element onto the base substrate does not overlap with an orthographic projection of the gate metal layer onto the base substrate, and an orthographic projection of the source and drain metal layer onto the base substrate; and the orthographic projection of the force sensing electrode element onto the base substrate and the orthographic projection of the anode layer onto the base substrate do not overlap with each other in a first direction; wherein the first direction is an extension direction of a gate in the gate metal layer;
or,
the lower substrate further comprises a buffer layer located between the base substrate and the poly-silicon layer; the force sensing electrode element is arranged on the buffer layer, and is covered by the gate insulation layer; the orthographic projection of the force sensing electrode element onto the base substrate does not overlap with the orthographic projection of the gate metal layer onto the base substrate, and the orthographic projection of the source and drain metal layer onto the base substrate; and the orthographic projection of the force sensing electrode element onto the base substrate and the orthographic projection of the anode layer onto the base substrate do not overlap with each other in the first direction.

16. The display device according to claim 15, wherein the gate metal layer comprises a first gate metal layer and a second gate metal layer arranged sequentially in a stack in a direction away from the poly-silicon layer; and
when the force sensing electrode element is arranged in the same layer with the anode layer on the planarization layer, the force sensing electrode element and the anode layer are formed in a same patterning process; or
when the force sensing electrode element is arranged on the buffer layer and covered by the gate insulation layer, the force sensing electrode element and the first gate metal layer are formed in a same patterning process; or
when the force sensing electrode element is arranged on the interlayer dielectric layer and covered by the planarization layer, the force sensing electrode element and the second gate metal layer are formed in a same patterning process.

17. The display device according to claim 15, wherein the lower substrate further comprises a common electrode arranged on the pixel definition layer; and the force sensing electrode element and the common electrode form a capacitor structure.

18. The display device according to claim 14, wherein the upper substrate comprises a touch panel substrate, an encapsulation substrate located on a side of the touch panel substrate facing the lower substrate, and a touch electrode element located on a side of the touch panel substrate facing away from the lower substrate;
wherein the force sensing electrode element and the touch electrode element form a capacitor structure.

19. The display device according to claim 18, wherein the touch electrode element comprises a drive touch electrode element and a sensing touch electrode element.

20. The display device according to claim 14, wherein the touch screen further comprises a force sensing detection circuit connected with the force sensing electrode element; the force sensing detection circuit comprises a channel selection circuit, an analog to digital converter, and a micro controller unit, wherein:
the channel selection circuit is configured to strobe a signal output by a force sensing electrode element subjected to a pressure applied by a user, and to input the signal to the analog to digital converter;
the analog to digital converter is configured to perform analog to digital conversion on the signal input by the channel selection circuit; and
the micro controller unit is configured to detect a magnitude and position of the pressure applied by the user according to a digital signal input by the analog to digital converter.
